(19) United States
(12) Patent Application Publication
(10) Pub. No.: US 2010/0012190 A1
(43) Pub. Date: Jan. 21, 2010

(54) NANOWIRE PHOTOVOLTAIC CELLS AND MANUFACTURE METHOD THEREOF

(76) Inventors: Hajime GOTO, Wako-shi (JP); Tomoaki Ohashi, Wako-shi (JP); Junichi Motohisa, Sapporo-shi (JP); Takashi Fukui, Sapporo-shi (JP)

Correspondence Address: BIRCH STEWART KOLASCH & BIRCH, PO BOX 747, FALLS CHURCH, VA, 22040-0747, US

(21) Appl. No.: 12/503,109

(22) Filed: Jul. 15, 2009

Related U.S. Application Data
(60) Provisional application No. 61/081,256, filed on Jul. 16, 2008.

(30) Foreign Application Priority Data
Apr. 24, 2009 (JP) 2009-106213

(51) Int. Cl. H01L 31/00; H01L 31/18

(52) U.S. Cl. 136/261; 438/96; 438/482; 257/E31.004; 257/E31.032

(57) ABSTRACT

Provided is a nanowire photovoltaic cell (1) including a semiconductor substrate (2) and a plurality of nanowire semiconductors (4) and (5) having a PN junction. The semiconductor substrate (2) and the nanowire semiconductors (4) and (5) are composed of one single crystal. The manufacture method of the nanowire photovoltaic cell includes a step of coating a part of a surface of the semiconductor substrate (2) with an amorphous film (3), and a step of developing a crystal of a material identical to that of the semiconductor substrate (2) through epitaxial growth on the uncoated surface of the semiconductor substrate (2) to form the plurality of nanowire semiconductors (4) and (5).

### BACKGROUND OF THE INVENTION

1. Field of the Invention

The present application relates to a nanowire photovoltaic cell composed of a nanowire semiconductor and a manufacture method thereof.

2. Description of the Related Art

It is known that a photovoltaic cell in general has a planar PN junction interface parallel to a surface of a substrate. Compared to the general photovoltaic cell, there has been known in recent years a photovoltaic cell composed of a fine linear semiconductor having a diameter of a nanometer order, commonly called as a nanowire, a nanorod and the like (hereinafter, described as nanowire photovoltaic cell).

There has been proposed a technique to make uneven the PN junction interface to improve the photoelectric conversion efficiency of the nanowire photovoltaic cell. According to the nanowire photovoltaic cell with the PN junction interface made uneven, since the area of the PN junction interface is made greater than that of a light acceptance surface, carriers lost due to recombination or the like are reduced, and as a result thereof, it is considered the photoelectric conversion efficiency can be improved.

There has been proposed a nanowire photovoltaic cell which includes a p-type Si semiconductor layer grown into a nanowire shape using microparticles of gold (Au), for example, as a catalyst, and an i-type Si semiconductor layer and an n-type Si semiconductor layer which are formed on the p-type Si semiconductor layer with an identical shape to the p-type Si semiconductor layer (for example, refer to B. Tian, X. Zheng, T. J. Kempa, Y. Fang, N. Yu, G. Yu, J. Huang and C. M. Lieber, “Coaxial Silicon nanowaires as solar cells and nanoelectronic power sources”, Nature 449, 885-890 (2007); and G. Zheng, W. Lu, S. Jin and C. M. Lieber, “Synthesis and Fabrication of High-Performance n-Type Silicon Nanowire Transistors”, Adv. Mater. 16, 1890-1893 (2004)).

The photovoltaic cell described in the above documents has a core-shell structure with the p-type Si semiconductor nanowire served as a core and the i-type Si semiconductor layer and the n-type Si semiconductor layer laminated on the core as a shell. The core-shell structured photovoltaic cell has the PN junction interface greater than the light acceptance surface. However, according to the nanowire photovoltaic cell, due to the reason that only one nanowire can be formed, it is impossible to manufacture a device capable of supplying electric power practically. Due to the reason that a metal catalyst, such as gold, is used in the growth of a nanowire for the nanowire photovoltaic cell, it is possible that the metal catalyst is absorbed into the nanowire as a dopant in the growth of the nanowire. The absorbed metal catalyst forms a deep energy level in the nanowire, which induces non-radiative recombination between an electron and a positive hole, and consequently, deteriorating the photoelectric conversion efficiency of the nanowire photovoltaic cell.

Due to the reason that the temperature cannot be raised to that where the epitaxial growth is conducted in the formation of the i-type Si semiconductor layer and the n-type Si semiconductor layer served as the shell of the nanowire photovoltaic cell, there arises a problem that the n-type Si semiconductor layer and the i-type Si semiconductor layer become poly-crystallized. This is because if a nanowire were heated to the temperature at which the epitaxial growth is conducted, the metal catalyst would be completely absorbed into the p-type Si semiconductor nanowire served as the core. As a result being grown at a low temperature, the i-type Si semiconductor layer and the n-type Si semiconductor layer served as the shell are turned into a wire structure with a crystal grain boundary contained therein. In the crystal grain boundary, there are a lot of dangling bonds existed, which induces recombination of excited electrons, and consequently, it is impossible to obtain the photoelectric conversion efficiency sufficiently.

There has been disclosed a nanowire photovoltaic cell which includes a p-type Si semiconductor grown into a nanowire shape and an n-type Si semiconductor layer which is formed on the p-type Si semiconductor layer with an identical shape to the p-type Si semiconductor layer (for example, refer to Japanese Patent Laid-open No. 2008-53730). According to the aforementioned photovoltaic cell, a porous template layer composed of nanoporous aluminum oxide is formed on a glass substrate covered with a doped degenerate polycrystalline silicon film, and the p-type Si semiconductor is made to grow on the porous template layer.

The nanowire photovoltaic cell disclosed in Japanese Patent Laid-open No. 2008-53730 has a core-shell structure with the p-type Si semiconductor nanowire served as a core and the n-type Si semiconductor layer laminated on the core as a shell. The core-shell structured photovoltaic cell has the PN junction interface greater than the light acceptance surface. However, according to the aforementioned nanowire photovoltaic cell, due to the reason that a lower junction is formed after the nanowire of the p-type Si semiconductor has been formed by using the porous holes in the template layer, and the lower junction is limited to a metallic or transparent electrode, therefore, the lower junction cannot be made of a single-crystal semiconductor material.

Due to the reason that the nanowire of the p-type Si semiconductor is made according to the VLS method using a metal catalyst and the metal catalyst will be remained at both ends of the nanowire, therefore, it is impossible to join the semiconductor and set it as the lower junction. In this regarding, although it is possible to form a nanowire without a metal catalyst remained at both ends of the nanowire by removing the metal catalyst through etching after the VLS growth or by forming the nanowire according to the electrochemical deposition method, it is impossible to form the lower junction composed of planar single-crystal semiconductor in the nanowire photovoltaic cell according to the subsequent epitaxial growth.

It has been described that in the aforementioned nanowire photovoltaic cell the porous template is located on the substrate and the substrate provides the lower junction, however, there is no description concerned on the necessity of the epitaxial growth. According to the VLS method, there exists a problem that metal materials will be remained on the interface between the substrate and the nanowire. Moreover, according to the electrochemical deposition method or the like, although metal materials are not remained on the interface between the substrate and the nanowire, it is not guaranteed that the substrate and the nanowire would continue to crystallize with the direction thereof maintained.

Furthermore, there has been proposed a nanowire photovoltaic cell which includes a Ta₂N layer formed on a metallic foil substrate composed of stainless steel, a nanowire of a p-type Si semiconductor formed on the Ta₂N layer, and an n-type Si semiconductor layer formed on the p-type Si semiconductor with an identical shape to the p-type Si semiconductor (For example, refer to L. Tsakalakos, J. Balch, J. Fronheiser, B. A. KoreVaar, O. Sulima and J. Rand, “Silicon nanowire solar cells”, APPLIED PHYSICS LETTERS 91, 233117 (2007)). The nanowire of the p-type Si semiconductor is formed on the Ta₂N layer by using a metal catalyst according to the VLS method. However, as aforementioned, there is a problem that the metal catalyst will be remained at both ends of the nanowire according to the VLS method.

According to the photovoltaic cells mentioned above, neither could supply electric power practically. For example, Voc, Isc, FF and η of the photovoltaic cell described by the last non-patent document are merely 0.13V, 3 mA/cm2, 0.28 and 0.06%, respectively, which is not preferred.

### SUMMARY OF THE INVENTION

The present invention has been accomplished in view of the aforementioned problems, and it is therefore an object of the present invention to provide a photovoltaic cell and a manufacture method thereof capable of constructing a device with a plurality of nanowire conductors arrayed therein and capable of supplying electric power practically.

To attain an object described above, a nanowire photovoltaic cell according to the present invention comprises a semiconductor substrate; and a plurality of nanowire semiconductors which are grown on the semiconductor substrate to form a PN junction, wherein the substrate and the plurality of nanowire semiconductors are composed of one single crystal.

According to the nanowire photovoltaic cell of the present invention, since the semiconductor substrate and the nanowire semiconductor are composed of one single crystal, contamination from a metal catalyst, defects on a crystal grain boundary or the like inside the nanowire semiconductor, and defects on an interface between the semiconductor substrate and the nanowire semiconductor and the like can be eliminated. According thereto, the nanowire photovoltaic cell of the present invention can improve photoelectric conversion efficiency thereof by reducing an electric resistance per unit area to supply electric power practically.

It is desirable for the nanowire photovoltaic cell according to the present invention to have a transparent insulator filled between gaps of the plurality of the nanowire semiconductors.

The energy band sometimes bends near a surface of a semiconductor material due to a surface structure and a superficial energy level thereof. In this case, electrons are drawn to the surface side of the nanowire conductor, thus, it is highly possible that excitons will lose due to the superficial recombination.

In this regard, it is desirable for the nanowire photovoltaic cell according to the present invention to have a passivation layer provided along the surface of the nanowire semiconductor to prevent the recombination. According to the provision of the passivation layer, it is possible to prevent the superficial recombination by forming a hetero junction.

The nanowire photovoltaic cell of the present invention can be advantageously manufactured according to a manufacture method comprising steps of coating a part of a surface of a semiconductor substrate with an amorphous film; and developing a crystal of an identical material to that of the semiconductor substrate through epitaxial growth on the surface of the semiconductor substrate which is uncoated by the amorphous film to form the plurality of nanowire semiconductors.

According to the manufacture method, it is possible to freely expose a part of the semiconductor substrate through the usage of a lithograph or a nanoimprint approach with respect to the amorphous film. Since a cut-off error of the semiconductor substrate can be excluded through an appropriate selection on a growth direction of the nanowire conductor and an orientation of the substrate, it is possible to yield the nanowire semiconductor completely vertical to the semiconductor substrate. Moreover, according to the manufacture method of the present invention, since epitaxial growth conditions during the epitaxial growth, it is possible to perform the epitaxial growth of the nanowire semiconductor in a lateral direction.

Thereby, according to the manufacture method, it is possible to construct a device with a plurality of nanowire semiconductors arrayed in a high density, which contributes to improvement of the photoelectric conversion efficiency.

Furthermore, it is desirable for the manufacture method to further include a step of filling a transparent insulator between gaps of the plurality of the nanowire semiconductors and exposing tip ends of the plurality of nanowire semiconductors by partially removing the transparent insulator after the plurality of nanowire semiconductors are buried under the transparent insulator. According to the manufacture method of the present invention, it is possible to fill the transparent insulator easily between the gaps of the plurality of the nanowire semiconductors through the aforementioned step.

### BRIEF DESCRIPTION OF THE DRAWINGS

FIG. 1 is a sectional view illustrating a nanowire photovoltaic cell according to a first embodiment of the present invention.

FIG. 2 is a sectional view illustrating a nanowire photovoltaic cell according to a variant example of the first embodiment of the present invention.

FIG. 3 is a sectional view illustrating a nanowire photovoltaic cell according to a second embodiment of the present invention.

FIG. 4 is a sectional view illustrating a nanowire photovoltaic cell according to a variant example of the second embodiment of the present invention.

### DETAILED DESCRIPTION OF THE PREFERRED EMBODIMENTS

Hereinafter, an embodiment of the present invention will be described in detail with reference to the drawings.

First, a nanowire photovoltaic cell 1 according to a first embodiment of the present invention will be described with reference to FIG. 1. The nanowire photovoltaic cell 1 is provided with an InP (111) A substrate 2, an amorphous SiO₂ film 3 formed on the InP (111) A substrate 2, and a p-type InP nanowire semiconductor 4 formed on a portion of the InP (111) A substrate 2 uncoated by the amorphous SiO₂ film 3. The p-type InP nanowire semiconductor 4 has an n-type InP semiconductor 5 formed along the surface thereof. Between the p-type InP semiconductor 4 and the n-type InP semiconductor 5, there is provided an i-type InP semiconductor (not shown). Thereby, the nanowire photovoltaic cell 1 has a core-shell structure with the p-type InP semiconductor 4 served as a core, the i-type InP semiconductor and the n-type InP semiconductor served as a shell.

The nanowire photovoltaic cell 1 is further provided with a transparent insulator 6 filled between gaps of a plurality of the p-type InP nanowire semiconductor 4, the i-type InP semiconductor and the n-type InP semiconductor 5, and a transparent electrode 7 formed on the transparent insulator 6. The transparent insulator 6 can be made of, for example, BCB resin (bis-benzocyclobutene manufactured by the DOW Chemical Company) The transparent electrode 7 can be made of, for example, Indium tin oxide (ITO) or the like.

Furthermore, the nanowire photovoltaic cell 1 is provided with a collector electrode 8 formed on the transparent electrode 7, and a back electrode 9 disposed on an opposite surface to the amorphous SiO₂ film 3 of the InP (111) A substrate 2. The collector electrode 8 can be made, for example, by evaporating Ag and Ni in order on the transparent electrode 7. The back electrode 9 can be made, for example, by evaporating Au-Zn alloy on the back surface of the substrate 2.

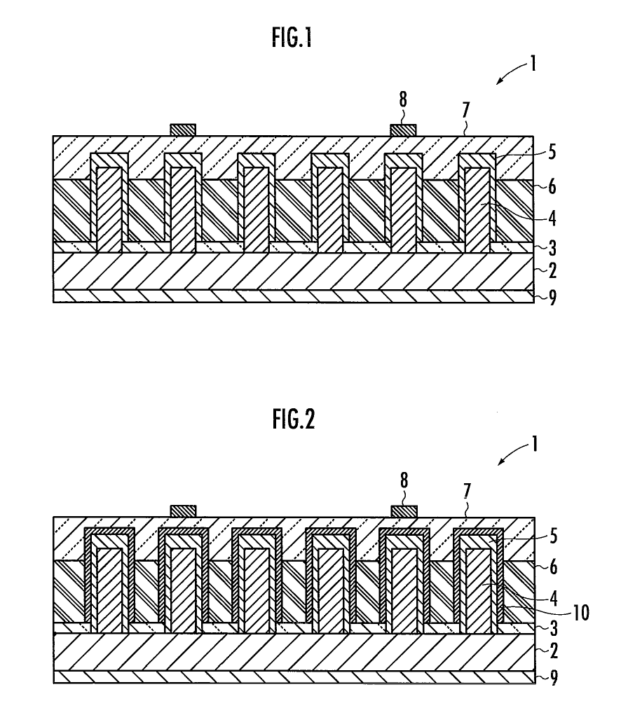

As illustrated in FIG. 2, it is also acceptable for the nanowire photovoltaic cell 1 to have a passivation layer 10 disposed on the either surface of the p-type InP nanowire semiconductor 4, the i-type InP semiconductor and the n-type InP semiconductor 5. As illustrated in FIG. 2, it is acceptable to cover totally the p-type InP semiconductor 4, the i-type InP semiconductor and the n-type InP semiconductor 5 above the amorphous SiO₂ film 3 with the passivation layer 10. It is also acceptable to cover at least a part of the side surfaces of the p-type InP semiconductor 4, the i-type InP semiconductor and the n-type InP semiconductor 5 with the passivation layer 10.

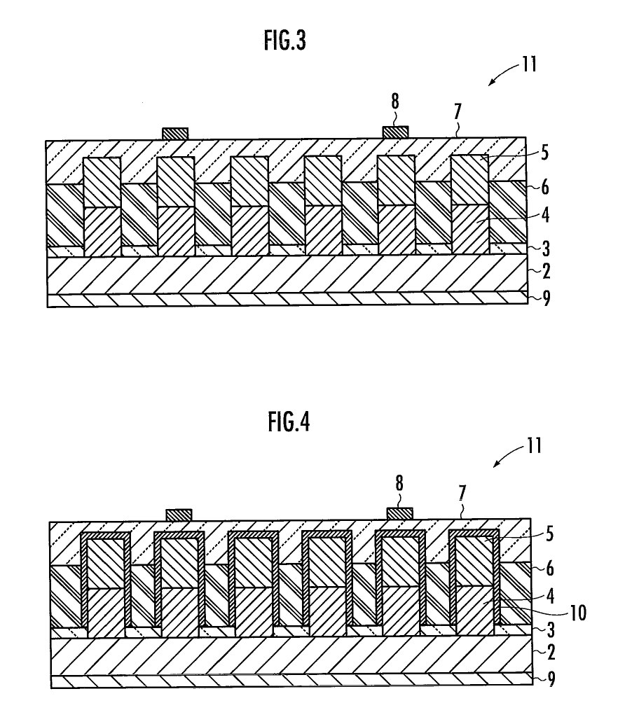

Hereinafter, a nanowire photovoltaic cell 11 according to a second embodiment of the present invention will be described with reference to FIG. 3. The nanowire photovoltaic cell 11 has the same structure as the nanowire photovoltaic cell 1 in FIG. 1, except that the n-type InP semiconductor 5 is joined with the p-type InP nanowire semiconductor 4 in the lengthwise direction to form the PN junction. In addition, between the p-type InP semiconductor 4 and the n-type InP semiconductor 5, there is provided an i-type InP semiconductor (not shown).

As illustrated in FIG. 4, it is also acceptable for the nanowire photovoltaic cell 11 to have the passivation layer 10 disposed on the either surface of the p-type InP nanowire semiconductor 4, the i-type InP semiconductor and the n-type InP semiconductor 5. As illustrated in FIG. 4, it is acceptable to cover totally the p-type InP semiconductor 4, the i-type InP semiconductor and the n-type InP semiconductor 5 above the amorphous SiO₂ film 3 with the passivation layer 10. It is also acceptable to cover at least a part of the side surfaces of the p-type InP semiconductor 4, the i-type InP semiconductor and the n-type InP semiconductor 5 with the passivation layer 10.

Hereinafter, a manufacture method of the nanowire photovoltaic cell 1 illustrated in FIG. 1 will be described.

First, the InP (111) A substrate 2, namely, the p-type semiconductor substrate, is washed clean, and an amorphous SiO₂ film 3 of a thickness of roughly 30 nm is coated on the surface of the InP (111) A substrate 2 by using a RF spatter provided with a SiO₂ target.

Thereafter, a positive resist is coated on the amorphous SiO₂ film 3, and the InP (111) A substrate 2 is set in an EB drawing device and a pattern is drawn on the positive resist. The pattern is configured, for example, to have circular holes with a diameter of 100 nm arrayed in a triangular lattice with a pitch of 400 nm.

The positive resist is developed after the pattern has been drawn thereon, and the InP (111) A substrate 2 is immersed in a BHF solution diluted 50 times to remove SiO₂ in the circular holes through etching. After the etching, the positive resist is removed.

The patterned InP (111) A substrate 2 with amorphous SiO₂ film 3 formed thereon is set in a reaction chamber of a MOVPE device. After the reaction chamber is degassed vacuum, it is replaced with H₂ gas. The flow rate and an exhaust velocity thereof are adjusted in a way that the total pressure of the chamber is maintained stable at 0.1 atm.

The substrate is heated until the temperature thereof reaches 660° C. with a mixture gas of TBP (Tertiarybutyl Phosphine) and a carrier gas (H₂) (Total pressure: 0.1 atm, TBP partial pressure: 1.1×10⁻⁴ atm) kept flowing. After the temperature of the substrate is raised to 660° C., the flowing gas is switched to a mixture gas of TMI (Trimethyl Lindium), DEZ (Diethyl Zinc) and TBP. The mixture gas is introduced into the reaction chamber to make the p-type InP semiconductor 4 grow into a nanowire shape through the epitaxial growth. The flow rate of each organic metal gas is adjusted so as to maintain the total pressure at 0.1 atm, the partial pressure of TMI at 5×10⁻⁶ atm, the partial pressure of DEZ at 1×10⁻⁶ atm and the partial pressure of TBP at 5×10⁻⁵ atm. After 10 mins, the flowing gas is switched back to the mixture gas of TBP and the carrier gas (Total pressure: 0.1 atm, TBP partial pressure: 1.1×10⁻⁴ atm) to complete the epitaxial growth of the p-type InP semiconductor 4.

Thereafter, the temperature of the substrate is lowered from 660° C. to 600° C. with the mixture gas of TBP and the carrier gas kept flowing. After the temperature reaches 600° C., the flowing gas is switched to a mixture gas of TMI, TBP, SiH₄ and the carrier gas. The mixture gas is introduced to the reaction chamber for 10 mins to make the n-type InP semiconductor 5 conduct the epitaxial growth on the surface of the p-type semiconductor 4. The flow rate of each organic metal gas is adjusted so as to maintain the total pressure at 0.1 atm, the partial pressure of TMI at 5×10⁻⁶ atm, the partial pressure of TBP at 5×10 ⁴ atm and the partial pressure of SiH₄ at 1×10 ⁶ atm. After 10 mins, the flowing gas is switched back to the mixture gas of TBP and the carrier gas (Total pressure: 0.1 atm, TBP partial pressure: 1.1×10⁻⁴ atm) to complete the epitaxial growth of the n-type InP semiconductor 5.

After the epitaxial growth of the p-type InP semiconductor 4 and the n-type InP semiconductor 5 is completed, the InP (111) A substrate 2 is removed out after being cooled by the flowing mixture gas of TBP and the carrier gas (Total pressure: 0.1 atm, TBP partial pressure: 1.1×10⁻⁴ atm).

According thereto, the nanowire semiconductor is yielded to have a core-shell structure with the p-type InP semiconductor 4 served as the core and the n-type InP semiconductor 5 served as the shell. Additionally, the p-type InP semiconductor 4 or the n-type InP semiconductor 5 yielded from the epitaxial growth may be of a shape of a cylinder or a hexagonal column. When it is a hexagonal column, the radius of the nanowire semiconductor is equivalent to the radius of an inscribed circle inside the hexagon in profile.

Thereafter, a BCB resin manufactured by the Dow Chemical Company is coated according to a spin coat method on the side of the p-type InP semiconductor 4 and the n-type InP semiconductor 5 of the InP (111) A substrate 2 with the p-type InP semiconductor 4 and the n-type InP semiconductor 5 grown into the nanowire shape according to the epitaxial growth. Subsequently, an annealing treatment is performed to cure the BCB resin in an inert gas atmosphere at 250° C. for 1 hr. Thereby, the transparent insulator 6 is yielded from the cured BCB resin.

The excessively coated BCB resin is etched away according to a Reactive Ion Etching (RIE) treatment by using a mixture gas of CF₄ and O₂ to expose a tip end of the nanowire semiconductor outside for 150 nm only. Then, the transparent electrode 7 made of ITO is filmed on the exposed nanowire side as a film by using a RF spatter device provided with an ITO target. The transparent electrode 7 is connected to the nanowire semiconductor.

Thereafter, an Au—Zn alloy is evaporated on a surface opposite to the surface of the InP (111) A substrate 2 coated with the amorphous SiO₂ film 3, and an annealing treatment is performed at 350° C. for 5 mins to form the back electrode 9. Then, Ag and Ni are evaporated in order on a partial portion of the surface of the transparent electrode 7 made of ITO to form the collector electrode 8, and consequently, the nanowire photovoltaic cell 1 is obtained.

Thereafter, a performance evaluation was performed on the nanowire photovoltaic cell 1 composed of the nanowire semiconductor having a core-shell structure in which the p-type InP semiconductor 4 is served as the core and the n-type InP semiconductor 5 is served as the shell. The nanowire semiconductor is configured to have a dimension of 1000 nm in height and 209 nm in diameter. The performance evaluation was performed by projecting simulated sunlight (AM 1.5) on the nanowire photovoltaic cell 1 to obtain an I-V curve thereof. The evaluation result on the performance of the nanowire photovoltaic cell 1 is shown in Table 1.

TABLE 1

| Voc | 0.432 V |
|---|---|
| Isc | 13.72 mA/cm² |
| FF | 0.569 |
| Pmax | 3.363 mV/cm² |
| η | 3.373% |

According to Table 1, it is obvious that the nanowire photovoltaic cell 1 of the present embodiment can supply electric power practically.

1. A nanowire photovoltaic cell, comprising:
a semiconductor substrate; and
a plurality of nanowire semiconductors which are grown on the semiconductor substrate to form a PN junction,
wherein the substrate and the plurality of nanowire semiconductors are composed of one single crystal.

2. The nanowire photovoltaic cell according to claim 1 further includes a transparent insulator which is filled between gaps of the plurality of the nanowire semiconductors.

3. The nanowire photovoltaic cell according to claim 1, further includes a passivation layer for preventing recombination which is provided along a surface of the nanowire semiconductor.

4. A manufacture method of a nanowire photovoltaic cell, comprising steps of:
coating a part of a surface of a semiconductor substrate with an amorphous film; and
developing a crystal of an identical material to that of the semiconductor substrate through epitaxial growth on the surface of the semiconductor substrate which is uncoated by the amorphous film to form the plurality of nanowire semiconductors.

5. The manufacture method of a nanowire photovoltaic cell according to claim 4 further includes a step of filling a transparent insulator between gaps of the plurality of the nanowire semiconductors and exposing tip ends of the plurality of nanowire semiconductors by partially removing the transparent insulator after the plurality of nanowire semiconductors are buried under the transparent insulator.

6. The nanowire photovoltaic cell according to claim 2, further includes a passivation layer for preventing recombination which is provided along a surface of the nanowire semiconductor.
